(19) United States
(12) Patent Application Publication
(10) Pub. No.: US 2014/0208014 A1
(43) Pub. Date: Jul. 24, 2014

(54) OPERATING A MEMORY

(71) Applicant: NOKIA CORPORATION, Espoo (FI)

(72) Inventor: Martti Kalevi Voutilainen, Espoo (FI)

(21) Appl. No.: 14/240,325

(22) PCT Filed: Aug. 29, 2011
(86) PCT No.: PCT/IB2011/053771

§ 371 Date: Feb. 21, 2014

(51) Int. Cl. H03M 7/30

(52) U.S. Cl. CPC H03M 7/3059
USPC 711/103; 711/154

(57) ABSTRACT

For enabling an efficient storage of received compressed data, an additional lossless compression is applied to the compressed data to obtain binary digits. The lossless compression is configured to result, on an average, in a higher percentage of binary digits having a first value than binary digits having a second value. The obtained binary digits are caused to be stored in a memory, wherein the storage of binary digits of the first value require less energy than or an equal amount of energy as the storage of binary digits of the second value.

### FIELD OF THE DISCLOSURE

The invention relates to the field of memories, and more specifically to the storage of data in a memory.

### BACKGROUND

Memories can be used in pure storage devices or in more complex devices, like mobile phones, laptops, tablet computers or navigation devices.

A memory may be used for storing system related data, like program code of operating systems, program code for applications, system parameters, status data, etc. A memory may equally be used for storing content that forms, for instance, the basis for a presentation to a user, like audio data, video data, image data, text data, etc.

Operating a memory requires energy. The energy may be provided by a battery of the device comprising the memory or by some external source of energy.

### SUMMARY OF SOME EMBODIMENTS OF THE INVENTION

An embodiment of a method according to the invention comprises receiving compressed data. The method further comprises applying an additional lossless compression to the compressed data to obtain binary digits, the lossless compression being configured to result, on an average, in a higher percentage of binary digits having a first value than binary digits having a second value. The method further comprises causing a storage of the obtained binary digits in a memory, the storage of binary digits of the first value requiring less energy than or the same amount of energy as the storage of binary digits of the second value.

A first embodiment of an apparatus according to the invention comprises one or more means for realizing the actions of the presented embodiment of the method according to the invention.

The means of this first embodiment of an apparatus can be implemented in hardware and/or software. They may comprise for instance a processor for executing computer program code for realizing at least a part of the required functions, a memory storing the program code, or both. Alternatively or in addition, they could comprise for instance circuitry that is designed to realize at least a part of the required functions, for example implemented in a chipset or a chip, like an integrated circuit.

A second embodiment of an apparatus according to the invention comprises a circuitry and/or at least one processor and at least one memory including computer program code, the circuitry and/or the at least one memory and the computer program code, with the processor, configured to cause an apparatus at least to perform the actions of the presented embodiment of a method according to the invention.

Moreover, an embodiment of a computer readable storage medium according to the invention is presented, in which computer program code is stored. The computer program code causes a device to perform the actions of the presented embodiment of a method according to the invention when executed by a processor.

The computer readable storage medium is a non-transient medium and could be for example a disk or a memory or the like. The computer program code could be stored in the computer readable storage medium in the form of instructions encoding the computer-readable storage medium. The computer readable storage medium may be intended for taking part in the operation of a device, like an internal or external hard disk of a computer, or be intended for distribution of the program code, like an optical disc or a memory stick.

It is to be understood that also the computer program code by itself has to be considered an embodiment of the invention.

An embodiment of a system according to the invention comprises an embodiment of an apparatus according to the invention and an apparatus configured to provide compressed data.

Any of the described apparatuses may comprise only the indicated components or one or more additional components. Furthermore, any of the described apparatuses may be a module or component for a device, or a fully functional device.

In one embodiment, the described method is an information providing method, and the described first apparatus is an information providing apparatus. In one embodiment, the means of the described first apparatus are processing means.

In certain embodiments of the described method, the method is a method for operating a memory. In certain embodiments of the described apparatuses, the apparatuses are apparatuses for operating a memory.

It is to be understood that any feature presented for a particular exemplary embodiment may also be used in combination with any other described exemplary embodiment of any category.

Further, it is to be understood that the presentation of the invention in this section is merely exemplary and non-limiting.

Other exemplary features of the present invention will become apparent from the following detailed description considered in conjunction with the accompanying drawings. It is to be understood, however, that the drawings are designed solely for purposes of illustration and not as a definition of the limits of the invention, for which reference should be made to the appended claims. It should be further understood that the drawings are not drawn to scale and that they are merely intended to conceptually illustrate the structures and procedures described herein.

### BRIEF DESCRIPTION OF THE FIGURES

FIG. 1 is a schematic block diagram of an exemplary embodiment of an apparatus according to the invention;

FIG. 2 is a flow chart illustrating an exemplary operation in the apparatus of FIG. 1;

FIG. 3 is a schematic block diagram of an exemplary embodiment of a system according to the invention; and

FIG. 4 is a flow chart illustrating an exemplary operation in the system of FIG. 3.

### DETAILED DESCRIPTION OF THE FIGURES

A significant portion of the energy that is needed for operating a memory may be consumed in writing data into the memory.

For example, with certain memories erasing data as well as reading data may require less energy than writing data into the memory. According to the document “A Hybrid Solid-State Storage Architecture for the Performance, Energy Consumption, and Lifetime Improvement” by S. Sun, Y. Joo, Y. Chen, D. Niu, Y. Xie, Y. Chen and H. Li, 987-1-4244-5659-8/09/$25.00 © 2009 IEEE, for instance, the energy required for a writing operation with an exemplary flash memory is 76 μJ/4 KB, while the energy required for a reading operation with the same flash memory is only 9.5 μJ/4 KB, and the energy required for an erasing operation with the same flash memory is only 16.5 μJ/4 KB.

Furthermore, also a wireless transmission of data extracted from a memory may require less energy than writing data to the memory. One of the lowest predictions for the power consumption that may be needed for future writing operations is about 0.28 nJ/bit for a ferroelectric NAND flash memory, which corresponds to a power reduction of 86% compared to a typical 1.8V FG-NAND memory with a power consumption of about 2 nJ/bit; see “A 1.0 V power supply, 9.3 GB/s write speed, Single-Cell Self-Boost program scheme for high performance ferroelectric NAND flash SSD” by K. Miyaji, S. Noda, T. Hatanaka, M. Takahashi, S. Sakai and K. Takeuchi, in Solid-State Electronics 58 (2011) 34-41. This is about ⅓ to ⅙ of the write energy of 1-2 nJ/bit that is typically required for a conventional phase change memory (PCM) or for a conventional NAND-flash memory. For data transmissions via a serial interface, the typical power consumption is currently about 10 pJ/bit, and it can be reduced to a value near 1 pJ/bit with a power-optimized design. This is two or three orders less than the writing energy per bit.

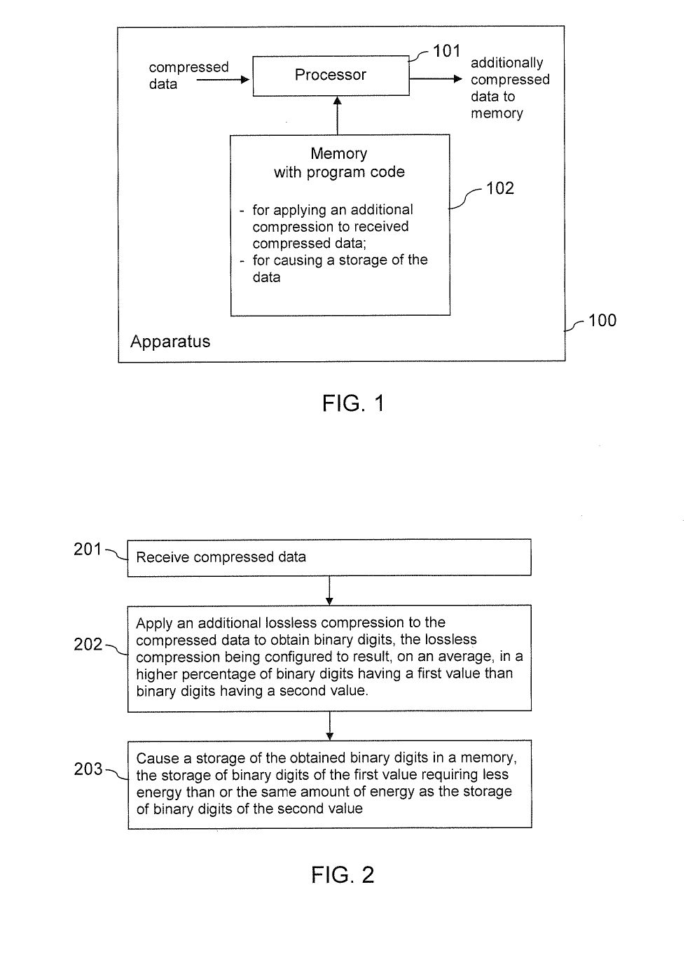

FIG. 1 is a schematic block diagram of an exemplary embodiment of an apparatus according to the invention.

Apparatus 100 comprises a processor 101 and, linked to processor 101, a memory 102. Memory 102 stores computer program code, which is designed for applying an additional compression to received compressed data and for causing a storage of the resulting data. Processor 101 is configured to execute computer program code stored in memory 102 in order to cause a device to perform desired actions.

In an alternative embodiment, the functions of processor 101 executing the computer program code could also be realized partly or entirely by a hardware circuitry.

An operation of apparatus 100 will now be described with reference to the flow chart of FIG. 2. The operation is an exemplary embodiment of a method according to the invention. Processor 101 and the program code stored in memory 102 may cause a device to perform the operation when the program code is retrieved from memory 102 and executed by processor 101.

The device, or a component of the device, receives compressed data. (action 201) That is, the compressed data can be provided to the device by another device, or from one component of the device to another component of the device.

The device applies an additional lossless compression to the compressed data to obtain binary digits. (action 202) The lossless compression is configured to result, on an average, in a higher percentage of binary digits having a first value than binary digits having a second value.

Applying an addition lossless compression to received compressed data is to be understood such that it does not require any full or partial decompression of the received compressed data. It is further to be understood that the application of the lossless compression is not required to result in a reduced amount of data for any type of received compressed data. When applied to data that has already been compressed using highly efficient primary coding schemes, like H.264 or MPEG-7, it may even result in an increase of data. The lossless compression thus only has to be suited in general to result in a reduced amount of data for some kind of input data.

Thereafter, the device causes a storage of the obtained binary digits in a memory. The memory is configured such that the storage of binary digits of the first value requires less energy than the storage of binary digits of the second value or essentially the same amount of energy as the storage of binary digits of the second value. (action 203) The memory could be memory 102 or an additional memory internal or external to apparatus 100.

Some types of memory may comprise for example a plurality of cells, and the state of each cell may be suited to represent the value of a binary digit. A first value may correspond to the default state of the cells. A second value may correspond to a state of a cell that is achieved by an active writing process, e.g. by injecting a charge to the cell or by some other action. The first state of a cell may be recovered by erasure. An erasure may only be applicable to a block of a plurality of cells in common. When binary data is to be stored to a selected area of the memory, e.g. a “page”, thus only the binary digits of the second value may have to be actively written to matched cells of the memory, since the cells that are matched to the first value already have a state corresponding to the first value. Only the active writing consumes a significant amount of energy. If the values of the digits can be “0” and “1”, it depends on the employed technology whether the second value requiring an active writing is the “0” or the “1”.

Other types of memory may equally comprise a plurality of cells, but enable a change between two states of a cell individually for each cell. Thus, previous data may be overwritten without a preceding general erasure, by changing only the state of each cell as required. The change of state may require essentially the same amount of energy in each direction.

The operation presented in FIG. 2 provides that a lossless compression is applied to data that is already received in a compressed form. In one embodiment, the lossless compression may be selected such that, in general, most of the resulting binary digits have a value that requires less energy than another value when storing the binary digits to a memory. This may have the effect that a reduced amount of data involves a high energy consumption when it is written into the memory. It is to be understood that requiring less energy may also mean requiring no energy for the actual storage, for example because no active writing is needed. In another embodiment, the lossless compression may be selected such that, in general, most of the resulting binary digits have the same value, while the storage of binary digits of the first value requires essentially the same amount of energy as the storage of binary digits of the second value. When overwriting old data in the memory, the probability is thus increased that most of the cells may keep their old state. This may have the effect that the energy consumption required for writing data to the memory is reduced.

Depending on the compression or coding scheme that has previously been applied to the received compressed data, also the total amount of data that has to be stored may be reduced further by the lossless compression. Often, compressed data still has some redundancy left and achieving up to 50% reduction of data by applying the additional lossless compression could be feasible.

The operation presented in FIG. 2 may also have the advantage that it can be used for any kind of received compressed data; that is, unlike an approach making use of transcoding or re-coding, the approach presented in FIG. 2 does not require any adaptation to a particular type of primary compression, and it is thus more flexible. Re-coding of the data would furthermore require at least a partial decoding of the received compressed data followed by a new encoding of the data, which may be less efficient. Transcoding is usually no lossless operation.

Apparatus 100 illustrated in FIG. 1 and the operation illustrated in FIG. 2 may be implemented and refined in various ways.

Certain embodiments may provide that the lossless compression is based on a Golomb-Rice coding scheme.

Golomb-Rice coding is a special case of Golomb coding. For a Golomb coding, a number n, with n≧0, is represented by means of two numbers q and r, with

$$q = floor ( \frac{n}{b} )$$

$$and$$

$$r = n - qb .$$

Here, b is a parameter that can be set to any desired value. With Rice coding, parameter b is selected specifically to be a power of two. This may have the effect that the implementation may be rather simple, using bit shifts and logical bit operations.

Truncated quotient q is coded as a sequence using q times a “1”, followed by a “0”. This coding may result in long sequences of “1”s. The rest r is coded using a truncated binary encoding that will not be presented in more detail here. With Rice coding, the value of r is simply written in binary form, with the number of binary digits corresponding to the exponent of 2 resulting in b. For example, with b=2²=4 r is always written with two binary digits.

It is to be understood, however, that any other lossless compression meeting the defined requirements may be used as well.

The employed lossless compression may be matched to the employed memory in various ways. For instance, if a memory is defined such that its states correspond to values of “0” and “1” and if the memory is further designed such that only the “0”s require an active writing, the lossless compression scheme may be selected such that it results on average in more binary digits having a value of “1” than binary digits having a value of “0”. However, for such a memory it would equally be possible to use a lossless compression scheme that results at first on average in more binary digits having a value of “0” than binary digits having a value of “1”, and inverting the first result before storage. Similarly, if a memory is defined such that its states correspond to values of “0” and “1” and if the memory is further designed such that only the “1”s require an active writing, the lossless compression scheme may be selected such that it results on average in more binary digits having a value of “0” than binary digits having a value of “1”. For such a memory, it would equally be possible to use a lossless compression scheme that results at first on average in more binary digits having a value of “1” than binary digits having a value of “0”s, and inverting the first result before storage. Thus, always the polarity of losslessly compressed data may be selected that has the highest number of bits that need no or little energy for active write operations.

Certain embodiments may thus provide that the lossless compression comprises inverting first compression results to obtain the binary digits that are to be stored. This may have the effect that the lossless compression scheme may be selected more flexibly and that the same lossless compression scheme may be employed for different kinds of memories, simply by adding in some cases an inversion step.

Certain embodiments may provide that the stored data is retrieved again from the memory, that a decompression is applied to the retrieved data to recover the compressed data as previously received. Since the compression was lossless, the previously received compressed data may be recovered exactly. The recovered compressed data may then be provided for transmission or for any other use, for example for presentation to a user.

This may have the effect that the apparatus handling the storage may interact with any other apparatus supporting the compression scheme that has been used for compressing the compressed data as received, regardless of whether the other apparatus uses an addition lossless compression as well or not. That is, there is no need to use an additional compression in every device, and the decision whether any apparatus should use an additional lossless compression can be made independently of the implementation of other, potentially co-operating apparatuses. For example, the additional lossless compression might be implemented only if lowest power consumption during data writing is desired and/or—depending on the use case—if the smallest possible memory use is desired.

Certain embodiments may provide that the received compressed data has been compressed with one of the following compression schemes: MP3 for audio data, H.264 (also referred to as MPEG-4/AVC) for video data, MPEG-2 for audio and video data, JPEG for image data, and MPEG-7 for description of multimedia content. It is to be understood, however, that the received compressed data may have been compressed with any other compression scheme as well, in particular, though not exclusively, with any other standardized compression scheme. Using compressed data in a standard format in particular for transmission between devices may have the effect that data compatibility is ensured.

Certain embodiments may provide that the compressed data is received via a wireless link. This could be any wireless short-range or close proximity link. Examples comprise a radio frequency identification (RFID) based link, a near field communication (NFC) based link, or a universal local storage (ULS) based link, as developed by Nokia Corporation. This may have the effect that the presented approach can be used when transferring a large amount of information, like high definition (HD) quality videos or large music albums or other bundled content sets, between mobile devices and storage services in a few seconds in a particular user friendly way.

Certain embodiments may provide that the memory is a volatile memory, while other embodiments may provide that the memory is a non-volatile memory (NVM). A non-volatile memory can be in particular any kind of mass memory, for instance a flash memory like a NAND flash memory or a NOR flash memory. A non-volatile memory could equally be a PCM, which may apply a high electric current pulse of short duration to a cell for obtaining a first, amorphous state of the cell to represent one value of a binary digit; and a lower current pulse of longer duration for changing to a second, crystalline state of the cell to represent the respective other value of a binary digit. A non-volatile memory can further be or be a part of, for example, a solid state drive (SSD), a multi media card (MMC), an embedded multi media card (eMMC), a universal flash storage (UFS), an embedded universal flash storage (eUFS), secure digital card (SD), an embedded secure digital card (eSD) or a secure digital input/output card (SDIO). Thus, the presented approach can be used flexibly for storage space within a complex device as well as for storage external to a device in a dedicated memory device. The memory can be for instance a single level cell (SLC) structure memory to facilitate the reduction of writing power consumption. The invention can be used with current memory technologies, and equally with any future memory technologies that require less energy for writing a second value than for writing a first value of binary digits, or that require essentially an equal amount of energy for writing either value of binary digits.

In an exemplary embodiment, apparatus 100 could comprise one or more additional components. It could comprise for instance an additional memory in which the twice compressed data is stored, a battery, a transceiver, and/or a user interface.

The apparatus 100 of FIG. 1 could be for instance a chip, a circuitry or an integrated circuit. It could also be a memory device, for instance in the form of a memory tag. A memory device could be for instance a radio frequency enabled memory device, or a device requiring a direct contact or a wired connection for an exchange of data. The apparatus 100 could further be a mobile device, like a mobile communication device, a laptop, a tablet computer, a navigation device, a gaming device and a media player. The apparatus 100 could further be a stationary device, like a server offering a storage service. It could also be any other kind of device implementing the defined features.

An exemplary embodiment of the invention could be employed for operating system (OS) compression, for example in modular architectures composed of independent subsystems. For example, mass storage could be a subsystem with a processor of which the operating system is stored in losslessly compressed format when the storage subsystem is not in use. Details of a multiprocessor subsystem have been presented in U.S. Pat. No. 7,903,642 and details of a non-volatile modular device have been presented in US application 2011/0099405 A1.

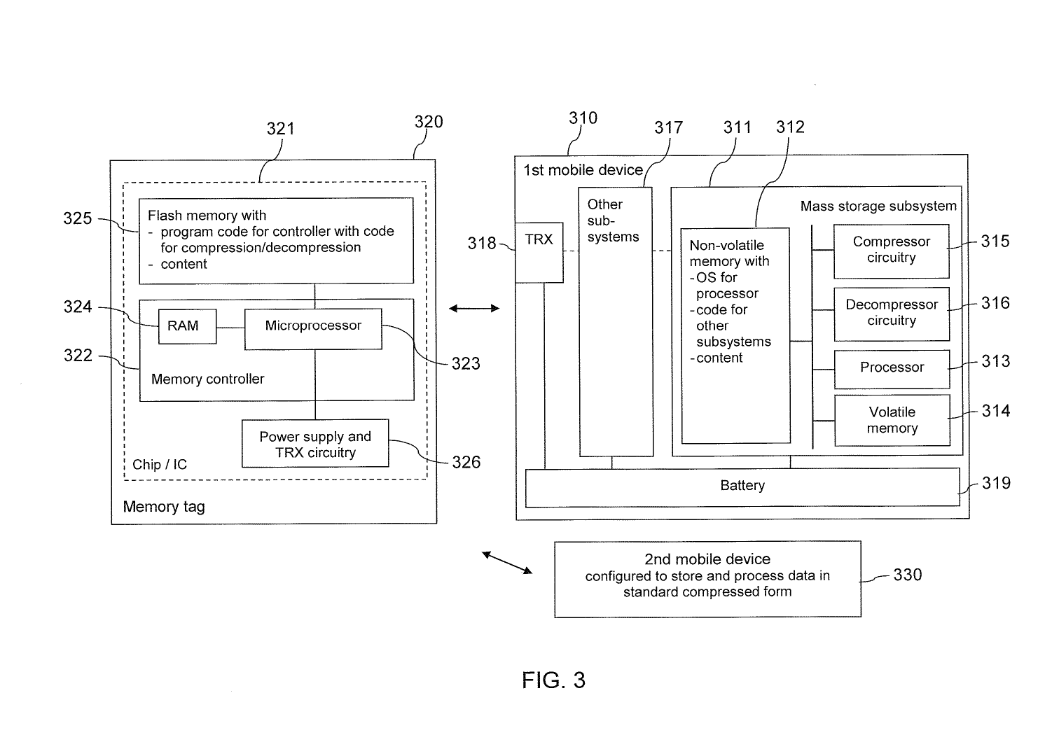

FIG. 3 is a schematic block diagram presenting an exemplary embodiment of a system according to the invention.

The system comprises a first mobile communication device 310, a memory tag 320 and a second mobile communication device 330.

By way of example, mobile communication device 310 is assumed to be a mobile phone. Mobile communication device 310 may include several subsystems 311, 317, a transceiver (TRX) 318, a battery 319 and various other components not shown.

One of the subsystems may be a mass storage subsystem 311. The mass storage subsystem 311 may include a non-volatile memory 312, a processor 313, a volatile memory 314, a compressor circuitry 315 and a decompressor circuitry 316. The components may be connected to each other by means of a bus or any other link. Memory 312 may store code for an operating system for subsystem 311 as well as associated parameters and state variables. The code may be copied to volatile memory 314 for execution by processor 313. Memory 312 may store in addition code for other subsystems, content data and any other kind of data. At least a part of the data stored in memory 312 has been compressed twice, e.g. first by an MP3 coding and then by Golomb-Rice coding based compression. Compressor circuitry 315 may comprise a hardware logic configured to apply a Golomb-Rice coding based data compression to data and decompressor circuitry 316 may comprise a hardware logic configured to apply Golomb-Rice coding based decompression to data.

Other subsystems 317 may include for instance a subsystem for handling a wireless exchange of data, a subsystem for handling presentation of audio data, etc.

Transceiver 318 may be configured to transmit and receive information via the air interface. Transceiver 318 could be for instance a near field communication transceiver, but equally any other kind of transceiver supporting a wireless exchange of data. Device 310 could comprise in addition for example a cellular communication transceiver and/or a wireless local area network (WLAN) transceiver.

The subsystems and other components may be linked to each other by some kind of data network.

Battery 319 may be connected to all components of device 310 requiring a power supply.

Some or all of the components of device 310, for instance the components of mass storage subsystem 311, may be integrated on a chip or in an integrated circuit.

Memory tag 320 comprises a memory 321, a memory controller 322 and a power supply and transceiver circuitry 326. These components or a part of these components may be integrated on a chip.

Memory controller 322 may comprise a microprocessor 323 and a random access memory (RAM) 324. Memory 325 could be for instance a NAND flash memory. It may store program code for memory controller 322, including compression and decompression code, and content data. The program code may be copied to RAM 324 for execution by processor 323.

Circuitry 326 may comprise a transceiver circuit for receiving data and providing the data to microprocessor 323 as well as for receiving data from microprocessor 323 and for transmitting the data. The transceiver circuit could be for instance a radio frequency (RF) transceiver configured to exchange data via the air interface. Circuitry 326 may comprise in addition a power supply circuit that powers microprocessor 323. The power supply circuit may obtain energy from radio transmissions by other devices 310, 330. Alternatively, the power supply circuit could comprise a rechargeable or non-rechargeable battery.

By way of example, mobile communication device 330 is assumed to be a laptop. Mobile communication device 330 is not enhanced according to an embodiment of the invention, but is able to process and store content that has been compressed by a standardized compression scheme, e.g. an MP3 coding.

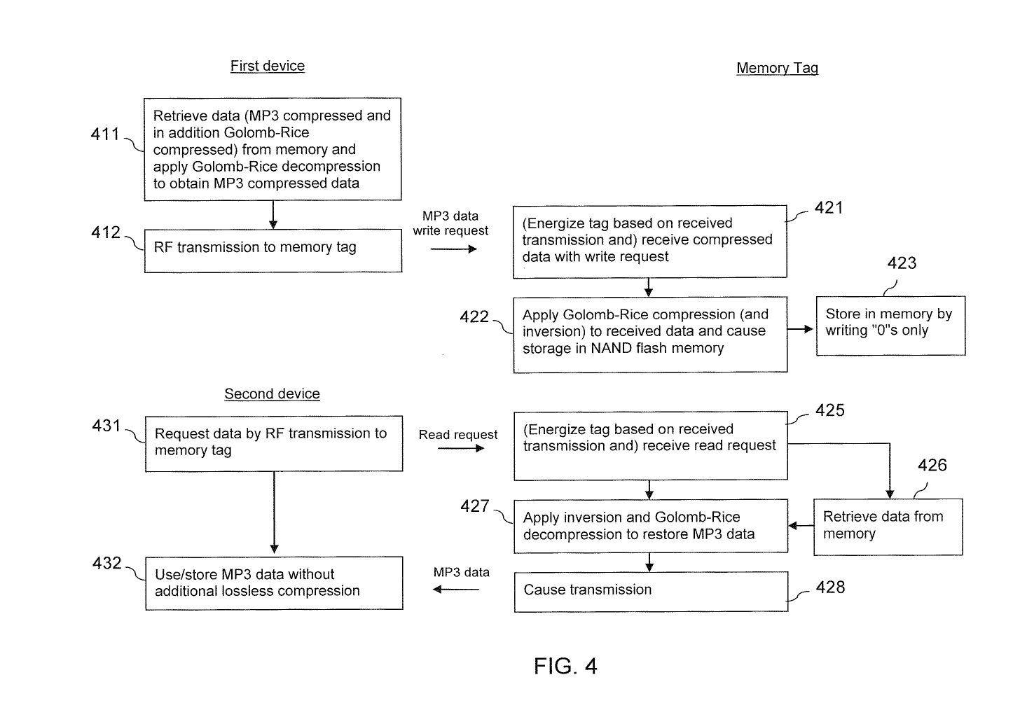

An exemplary operation in the system of FIG. 3 will now be described with reference to the flow chart of FIG. 4. Device 310 is caused by processor 313 to perform the actions presented on the top left-hand side of FIG. 4 when executing program code that is stored in memory 314. Memory tag 320 is caused by processor 323 to perform the actions presented on the right-hand side of FIG. 4 when executing program code that is stored in memory 324. Device 330 is configured to perform the actions presented on the lower left-hand side of FIG. 4.

Processor 313 causes content data, which is MP3 and Golomb-Rice compressed, to be retrieved from memory 312, and causes decompressor circuitry 316 to apply a Golomb-Rice based decompression to the retrieved data to obtain MP3 coded data. (action 411) The data had earlier been received by mass storage subsystem 311 as MP3 coded data and it had been Golomb-Rice compressed in addition by compressor circuitry 315 for storage in memory 312.

Processor 313 then provides the MP3 coded data for transmission to memory tag 320. The actual transmission via transceiver 318 could be handled by one of the other subsystems 317. The transmission could comprise the data along with a write request, that is, a request to store the data in memory tag 320. (action 412)

It is to be understood that also the operating system for processor 313 could be stored in lossless compressed form in memory 312 and only be decompressed by decompressor circuitry 316 and stored in decompressed for in volatile memory 314 when mass storage subsystem 311 is to be used.

Memory tag 320 receives the transmission from device 310 via circuitry 326. In case memory tag 320 does not comprise a battery, circuitry 326 obtains energy from the transmission for powering microprocessor 323. In addition, circuitry 326 forwards the received MP3 coded content data and the received write request to microprocessor 323. (action 421) Upon powering up, microprocessor 323 causes all or part of the stored program code to be loaded to RAM 324 and uses the code from RAM 324 for its operation.

Microprocessor 323 applies at first a Golomb-Rice coding based lossless compression to the received MP3 coded content data. Depending on the type of compression used for the received compressed data—in the present case the MP3 coding—the lossless compression may further reduce the amount of the received content data. In addition, the lossless compression ensures that the data is in a binary form that includes long sequences of “1”s. If the lossless compression was selected instead to result in binary digits with long sequences of “0”s, microprocessor 323 would apply in addition an inversion to the binary digits to obtain data in a binary form that includes long sequences of “1”s.

Microprocessor 323 then causes a storage of the twice compressed data in memory 321. (action 422)

The data is stored in memory 321 by actively writing only digits having a value of “0”. (action 423) Digits having a value of “1” are available by default.

At a later point of time, device 330 may request memory tag 320 to provide stored data by transmitting a read request via the air interface. (action 431)

Memory tag 320 receives the transmission including the read request from device 330 via circuitry 326. In case memory tag 320 does not comprise a battery, circuitry 326 obtains energy from the transmission for powering microprocessor 323. In addition, circuitry 326 forwards the read request to microprocessor 323. (action 425) Upon being powered up, microprocessor 323 causes all or part of the stored program code to be loaded to RAM 324 and uses the code from RAM 324 for its operation.

Based on the read request, microprocessor 323 retrieves at first the requested, twice compressed content data from memory 325. (action 426) Microprocessor 323 then applies a Golomb-Rice coding based decompression to the retrieved data. (action 427) The resulting data corresponds to single compressed data in the form it was received by memory tag 320; it could correspond for instance to the MP3 compressed data as previously provided by device 310. Microprocessor 323 causes a transmission of the content data via circuitry 326. (action 428)

Device 330 receives the requested compressed content data. The data may be stored at device 330 without applying an additional lossless compression and/or be decoded and presented to a user. For example, if the received data is MP3 coded audio data, the decoded audio data could be presented to a user via speakers of device 330. (action 432)

Thus, even though device 330 is not configured to apply a Golomb-Rice coding based decompression, it is able to make use of the data stored in memory tag 320.

Certain embodiments of the invention may have the advantage that they reduce the power consumption required for writing data to a memory. This may partly be achieved by reducing the amount of data that is to be stored by applying an additional lossless compression to already compressed data. This may be the case for any already compressed data that still provides significant redundancy. Standard compressed data may still have some redundancy left and up to 50% reduction of compressed data could be feasible. This may also result in significant cost savings, because every gigabyte (GB) of a non-volatile memory may cost 1-3 [symbol] ; and e.g. 30% reduction of required storage space means 30% reduction of costs of the most expensive component of a device.

In addition—and even in cases in which the additional lossless compression might rather increase than reduce the total amount of data due to a very efficient primary compression—a reduction of the power consumption required for writing data to a memory may be achieved by reducing the percentage of the data that has to be written actively to the memory or that involves a particularly high energy consumption in active writing.

Certain embodiments of the invention may have the advantage that the lossless compression can be apparatus dependent, while all apparatuses between which data is transmitted can still understand the data they receive.

FIGS. 2 and 4 may also be understood to represent exemplary functional blocks of computer program codes for operating a memory.

The processors used in any of the above described embodiments could also be used for various additional operations.

Any presented connection in the described embodiments is to be understood in a way that the involved components are operationally coupled. Thus, the connections can be direct or indirect with any number or combination of intervening elements, and there may be merely a functional relationship between the components.

Further, as used in this text, the term ‘circuitry’ refers to any of the following:

(a) hardware-only circuit implementations (such as implementations in only analog and/or digital circuitry)

(b) combinations of circuits and software (and/or firmware), such as: (i) to a combination of processor(s) or (ii) to portions of processor(s)/ software (including digital signal processor(s)), software, and memory(ies) that work together to cause an apparatus, such as a tag or server, to perform various functions) and

(c) to circuits, such as a microprocessor(s) or a portion of a microprocessor(s), that require software or firmware for operation, even if the software or firmware is not physically present.

This definition of ‘circuitry’ applies to all uses of this term in this text, including in any claims. As a further example, as used in this text, the term ‘circuitry’ also covers an implementation of merely a processor (or multiple processors) or portion of a processor and its (or their) accompanying software and/or firmware. The term ‘circuitry’ also covers, for example, a baseband integrated circuit or applications processor integrated circuit for a device.

Any of the processors mentioned in this text could be a processor of any suitable type. Any processor may comprise but is not limited to one or more microprocessors, one or more processor(s) with accompanying digital signal processor(s), one or more processor(s) without accompanying digital signal processor(s), one or more special-purpose computer chips, one or more field-programmable gate arrays (FPGAS), one or more controllers, one or more application-specific integrated circuits (ASICS), or one or more computer(s). The relevant structure/hardware has been programmed in such a way to carry out the described function.

Any of the memories mentioned in this text could be implemented as a single memory or as a combination of a plurality of distinct memories, and may comprise for example a read-only memory, a random access memory, a flash memory or a hard disc drive memory etc.

Moreover, any of the actions described or illustrated herein may be implemented using executable instructions in a general-purpose or special-purpose processor and stored on a computer-readable storage medium (e.g., disk, memory, or the like) to be executed by such a processor. References to ‘computer-readable storage medium’ should be understood to encompass specialized circuits such as FPGAs, ASICs, signal processing devices, and other devices.

The functions illustrated by processor 101 in combination with memory 102, or by processor 313 in combination with memory 312 and circuitry 315 and 316, or by processor 323 in combination with memory 321, can be viewed as means for receiving compressed data, means for applying an additional lossless compression to the compressed data to obtain binary digits, the lossless compression being configured to result, on an average, in a higher percentage of binary digits having a first value than binary digits having a second value, and means for causing a storage of the obtained binary digits in a memory, the storage of binary digits of the first value requiring less energy than or an equal amount of energy as the storage of binary digits of the second value.

The program codes in memory 102 or memory 321 can also be viewed as comprising such means in the form of functional modules.

It will be understood that all presented embodiments are only exemplary, that features of these embodiments may be omitted or replaced and that other features may be added. Any mentioned element and any mentioned method step can be used in any combination with all other mentioned elements and all other mentioned method step, respectively. It is the intention, therefore, to be limited only as indicated by the scope of the claims appended hereto.

1-22. (canceled)

23. A method comprising:
receiving compressed data;
applying an additional lossless compression to the compressed data to obtain binary digits, the lossless compression being configured to result, on an average, in a higher percentage of binary digits having a first value than binary digits having a second value; and
causing a storage of the obtained binary digits in a memory, the storage of binary digits of the first value requiring less energy than or an equal amount of energy as the storage of binary digits of the second value.

24. The method according to claim 23, wherein the lossless compression is based on a Golomb-Rice coding scheme.

25. The method according to claim 23, wherein the lossless compression comprises inverting first compression results to obtain the binary digits.

26. The method according to claim 23, the method further comprising retrieving the binary digits from the memory and applying a decompression to the retrieved binary digits to recover the data as received.

27. The method according to claim 23, wherein the compressed data is received via a wireless link.

28. The method according to claim 23, wherein the memory is at least a part of at least one of
a non-volatile memory;
a single level cell structure memory;
a flash memory;
a NAND flash memory;
a phase change memory;
a solid state drive;
a multi media card;
an embedded multi media card;
a universal flash storage;
an embedded universal flash storage;
secure digital card;
an embedded secure digital card; and
a secure digital input/output card.

29. The method according to claim 23, wherein the received compressed data has been compressed with one of the following compression schemes:
MP3;
H.264;
MPEG-2;
JPEG; and
MPEG-7.

30. An apparatus comprising means for realizing the actions of the method of claim 23.

31. The apparatus according to claim 30, further comprising at least one of:
the memory;
a battery;
a transceiver;
a wireless transceiver; and
a user interface.

32. The apparatus according to claim 30, wherein the apparatus is one of:
a chip;
an integrated circuit;
a memory device;
a memory tag;
a radio frequency enabled memory device;
a mobile device;
a mobile communication device; and
a stationary device.

33. An apparatus comprising at least one of
a circuitry; and
at least one processor and at least one memory including computer program code;
at least one of the circuitry and the at least one memory and the computer program code, with the at least one processor, configured to cause the apparatus at least to perform:
receive compressed data;
apply an additional lossless compression to the compressed data to obtain binary digits, the lossless compression being configured to result, on an average, in a higher percentage of binary digits having a first value than binary digits having a second value; and
cause a storage of the obtained binary digits in a memory, the storage of binary digits of the first value requiring less energy than or an equal amount of energy as the storage of binary digits of the second value.

34. The apparatus according to claim 33, wherein the lossless compression is based on a Golomb-Rice coding scheme.

35. The apparatus according to claim 33, wherein the lossless compression comprises inverting first compression results to obtain the binary digits.

36. The apparatus according to claim 33, wherein at least one of the circuitry and the at least one memory and the computer program code, with the at least one processor, further configured to cause the apparatus to retrieve the binary digits from the memory and to apply a decompression to the retrieved binary digits to recover the data as received.

37. The apparatus according to claim 33, wherein the compressed data is received via a wireless link.

38. The apparatus according to claim 33, wherein the memory is at least a part of at least one of
a non-volatile memory;
a single level cell structure memory;
a flash memory;
a NAND flash memory;
a phase change memory;
a solid state drive;
a multi media card;
an embedded multi media card;
a universal flash storage;
an embedded universal flash storage;
secure digital card;
an embedded secure digital card; and
a secure digital input/output card.

39. The apparatus according to claim 33, wherein the received compressed data has been compressed with one of the following compression schemes:
MP3;
H.264;
MPEG-2;
JPEG; and
MPEG-7.

40. The apparatus according to claim 33, further comprising at least one of:
the memory;
a battery;
a transceiver;
a wireless transceiver; and
a user interface.

41. The apparatus according to claim 33, wherein the apparatus is one of:
a chip;
an integrated circuit;
a memory device;
a memory tag;
a radio frequency enabled memory device;
a mobile device;
a mobile communication device; and
a stationary device.

42. A computer readable storage medium in which computer program code is stored, the computer program code causing an apparatus to perform the following when executed by the processor:
receiving compressed data;
applying an additional lossless compression to the compressed data to obtain binary digits, the lossless compression being configured to result, on an average, in a higher percentage of binary digits having a first value than binary digits having a second value; and
causing a storage of the obtained binary digits in a memory, the storage of binary digits of the first value requiring less energy than or an equal amount of energy as the storage of binary digits of the second value.
